(19) United States
(12) Patent Application Publication
(10) Pub. No.: US 2015/0079800 A1
(43) Pub. Date: Mar. 19, 2015

(54) METHOD OF MANUFACTURING SEMICONDUCTOR DEVICE

(71) Applicant: Kabushiki Kaisha Toshiba, Tokyo (JP)

(72) Inventor: Tomoyuki Iguchi, Ishikawa-ken (JP)

(73) Assignee: Kabushiki Kaisha Toshiba, Tokyo (JP)

(21) Appl. No.: 14/202,795

(22) Filed: Mar. 10, 2014

(30) Foreign Application Priority Data
Sep. 13, 2013 (JP) 2013-190235

(51) Int. Cl. H01L 21/3213

(52) U.S. Cl. CPC H01L 21/32135
USPC 438/714

(57) ABSTRACT

According to one exemplary embodiment, a method of manufacturing a semiconductor device is provided, the method including: dry-etching an aluminum film containing silicon with a first etching gas containing halogen to decrease the thickness of the aluminum film; and dry-etching the aluminum film with a second etching gas containing inert gas.

### CROSS-REFERENCE TO RELATED APPLICATION

This application is based upon and claims the benefit of priority from Japanese Patent Application No. 2013-190235, filed Sep. 13, 2013; the entire contents of which are incorporated herein by reference.

### FIELD

Exemplary embodiments described herein generally relate to a method of manufacturing a semiconductor device.

### BACKGROUND

As an electrode pad of a semiconductor device, an aluminum film containing silicon is widely used from the viewpoint of the bonding property and reliability.

Such a silicon-containing aluminum film is etched by dry-etching in many cases.

### DESCRIPTION OF THE DRAWINGS

FIGS. 1A to 1C are cross-sectional views illustrating a method of manufacturing a semiconductor device according to a first embodiment.

FIGS. 2A to 2C are cross-sectional views illustrating a method of manufacturing a semiconductor device according to a comparative case.

FIG. 3 is a graph illustrating effects of the first embodiment.

FIG. 4A is a scanning electron microscopic (SEM) image of a sample according to the comparative example, and

FIG. 4B is an SEM image of a sample according to the first embodiment.

### DETAILED DESCRIPTION

Exemplary embodiments are to provide a method capable of manufacturing a semiconductor device including a silicon-containing aluminum film with high shape accuracy.

In general, according to one exemplary embodiment, there is provided a method of manufacturing a semiconductor device including: dry-etching an aluminum film containing silicon with a first etching gas containing halogen to decrease the thickness of the aluminum film (first etching); and dry-etching the aluminum film with a second etching gas containing inert gas (second etching).

### First Embodiment

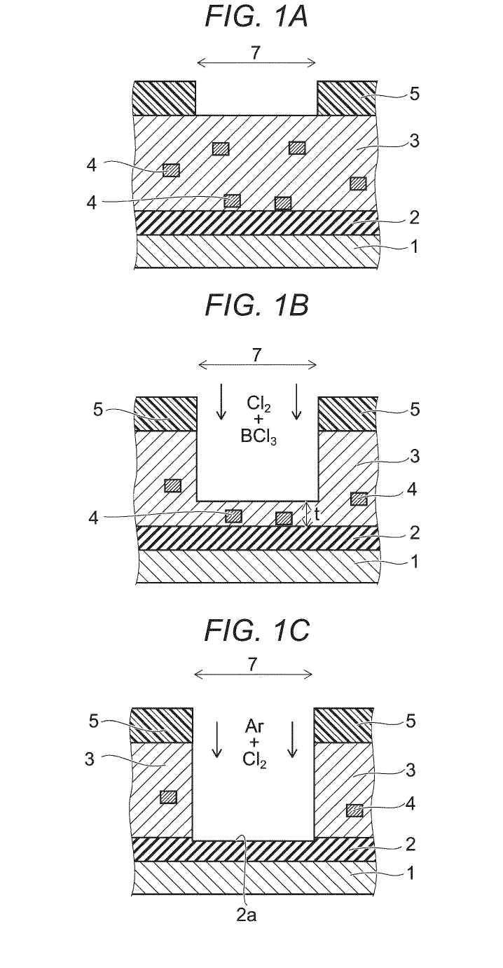

Hereinafter, embodiments will be described with reference to the drawings. First, a first embodiment will be described. FIGS. 1A to 1C are cross-sectional views illustrating a method of manufacturing a semiconductor device according to this embodiment.

First, as illustrated in FIG. 1A, an interlayer insulating film 2 formed of a silicon oxide (SiO) and having a thickness of, for example, 300 nm is formed on a silicon wafer 1 by, for example, chemical vapor deposition (CVD). Next, a silicon-containing aluminum film 3 (hereinafter, also referred to as “AlSi film 3”) is formed by sputtering. A major component of the AlSi film 3 is aluminum (Al) and contains, for example, 1 mass % of silicon (Si). The thickness of the AlSi film 3 is, for example, in a range from 3 μm to 5 μm and is assumed as 4 μm. At this time, in order to increase coverage of the AlSi film 3 by allowing the AlSi film 3 to reflow, the AlSi film 3 is sputtered while heating the silicon wafer 1. Temperatures at this time are, for example, lower than 455° C. and is assumed as about 430° C. As a result, silicon is precipitated in the AlSi film 3, and a nodule 4 is formed of the silicon. A maximum diameter of the nodule 4 is, for example, about several hundreds nm. That is, a maximum thickness (maximum height) of the nodule 4 is about several hundreds nm. Next, a photoresist material is applied onto the AlSi film 3 and is patterned with a lithography method. As a result, a resist mask 5 is formed.

Next, as illustrated in FIG. 1B, first dry-etching is performed by using the resist mask 5 as a mask. At this time, gas containing halogen such as chlorine is used as etching gas. The first dry-etching is not performed to the extent that the AlSi film 3 is completely removed in an opening region 7 which is not covered with the resist mask 5. The first dry-etching is stopped immediately before the complete removal of the AlSi film 3. At this time, it is preferable that a residual film thickness of the AlSi film 3 be sufficiently greater than an estimated maximum thickness of the nodule 4. For example, the residual film thickness t of the AlSi film 3 is greater than or equal to 300 nm.

For example, as the etching gas, a mixture of chlorine gas (Cl₂) and boron trichloride gas (BCl₃) is used. It is assumed that a flow rate of the chlorine gas (Cl₂) is 100 sccm, a flow rate of the boron trichloride gas (BCl₃) is 100 sccm, a pressure is 0.1 Pa, and a power (Source/Bias) is (1000/200 W). Under these conditions, etching is performed for a time corresponding to 2.5 μm in terms of a pure aluminum film containing no silicon.

Next, as illustrated in FIG. 1C, second dry-etching is performed using another etching gas. At this time, a mixture of inert gas and halogen gas is used as the etching gas. As the halogen gas, for example, chlorine gas is used. In addition, as the inert gas, for example, argon gas (Ar) is used. It should be noted that nitrogen gas (N₂) may be used as the inert gas. The second dry etching is performed until the AlSi film 3 is completely removed in the opening region 7, such that a top surface 2a of the interlayer insulating film 2 is exposed. A flow ratio of the inert gas to the entire etching gas is, for example, 30% to 75% by volume in the standard state.

For example, as the etching gas, a mixture of argon gas (Ar) and chlorine gas (Cl₂) is used. It is assumed that a flow rate of the argon gas (Ar) is 80 sccm, a flow rate of the chlorine gas (Cl₂) is 40 sccm, a pressure is 1.5 Pa, and a power (Source/Bias) is (1000/200 W). Under these conditions, etching is performed for a time corresponding to 2.0 μm in terms of a pure aluminum film containing no silicon.

It should be noted that the etching gas of the first dry-etching may also contain inert gas. However, a flow ratio of inert gas in the etching gas of the first dry-etching is controlled to be lower than a flow ratio of inert gas in the etching gas of the second dry-etching.

In the second dry-etching, not only a base material made of aluminum but also the nodule 4 made of silicon is removed by etching. In addition, an upper portion of the interlayer insulating film 2 is slightly dug in the opening region 7. However, a trace of the nodule 4 is small in the top surface 2a of the interlayer insulating film 2.

Next, through necessary subsequent treatments, a semiconductor device is manufactured. The semiconductor device according to this exemplary embodiment is, for example, a power semiconductor device, and the AlSi film 3 forms an electrode pad of the device. By forming the electrode pad using the silicon-containing aluminum film instead of a pure aluminum film, the bonding property and reliability of the electrode pad are improved.

Next, the operation and advantageous effects of the embodiment will be described. In this embodiment, a part of the AlSi film 3 positioned inside the opening region 7 is etched by the first dry-etching illustrated in FIG. 1B. At this time, since the etching gas contains halogen gas, the AlSi film 3 is mainly etched by a chemical reaction. In addition, aluminum is selectively etched to silicon.

The residual portion of the AlSi film 3 is etched by the second dry-etching illustrated in FIG. 1C. In the second dry-etching, since the etching gas contains inert gas, the AlSi film 3 is etched not only by a chemical reaction but also by physical sputtering. Accordingly, silicon is also etched at an etching rate similar to that of aluminum. As a result, the nodule 4 contained in the AlSi film 3 is also removed along with the base material.

As a result, a shape of the top surface 2a of the interlayer insulating film 2 in the opening region 7 is flat substantially without being reflected from a shape of the nodule 4. In this way, according to this embodiment, a substrate surface after etching can be finished in a flat shape, and a semiconductor device including the silicon-containing aluminum film can be manufactured with a high shape accuracy. As a result, in the manufactured semiconductor device, shape defects are difficult to occur, and characteristic defects caused by the shape defects are also difficult to occur.

In addition, by performing the first dry-etching before the second dry-etching, most part of the AlSi film 3 in the opening region 7 can be etched at a high etching rate while reserving the resist mask 5. As a result, the AlSi film 3 can be efficiently etched, and a semiconductor device can be manufactured with high productivity.

On the other hand, when it is assumed that the AlSi film 3 is etched by only the second dry-etching without performing the first dry-etching, an etching time is increased because the etching rate of the second dry-etching is lower than that of the first dry-etching. As a result, the productivity of a semiconductor device deteriorates. In addition, it is difficult to reserve the resist mask 5 until the etching of the AlSi film 3 is completed.

Further, in this embodiment, the etching gas of the second dry-etching contains halogen gas. As a result, since the AlSi film 3 can be etched not only by a sputtering effect due to inert gas but also by a chemical reaction due to halogen, the etching rate of the second dry-etching can be increased.

In this embodiment, a barrier layer made of, for example, titanium nitride (TiN) may be provided between the interlayer insulating film 2 and the AlSi film 3. In the second dry-etching, this barrier layer is selectively etched to the interlayer insulating film 2 and is removed from the opening region 7.

### Comparative Case

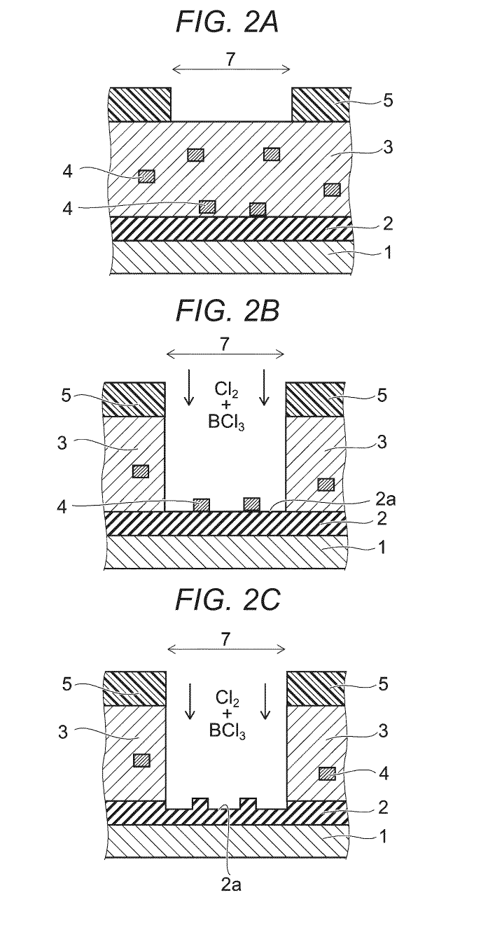

Next, a comparative example will be described. In this comparative example, an AlSi film 3 is etched by only the first dry-etching without performing the second dry-etching. FIGS. 2A to 2C are cross-sectional views illustrating a method of manufacturing a semiconductor device according to the comparative example.

As illustrated in FIG. 2A, in this comparative example, an interlayer insulating film 2 is formed on a silicon wafer 1, and a silicon-containing aluminum film (AlSi film) 3 is formed thereon. As a result, a resist mask 5 is formed. In the AlSi film 3, a nodule 4 made of silicon is precipitated.

As illustrated in FIG. 2B, the first dry-etching is performed by using the resist mask 5 as a mask. As a result, the AlSi film 3 in an opening region 7 is removed. For example, etching is performed for a time corresponding to 4.5 μm in terms of a pure aluminum film containing no silicon. At this time, since aluminum is preferentially etched to silicon, the nodule 4 remains on the interlayer insulating film 2 after an aluminum portion is removed.

As illustrated in FIG. 2C, when the first dry-etching is further continued so as to remove the nodule 4 on the interlayer insulating film 2, the nodule 4 is removed; however, a part of the interlayer insulating film 2 which is not covered with the nodule 4 is dug. As a result, the shape of the nodule 4 is transferred onto the top surface 2a of the interlayer insulating film 2. Therefore, the flatness of the top surface 2a of the interlayer insulating film 2 is decreased.

Accordingly, when it is assumed that the first dry-etching is stopped in a state illustrated in FIG. 2B and a subsequent process is started, the nodule 4 is peeled off in the subsequent process, which causes a problem. In addition, when it is assumed that the first dry-etching is stopped in a state illustrated in FIG. 2C and a subsequent process is started, a coverage of a film to be covered in the subsequent process is decreased by convex and concave portions of the top surface 2a of the interlayer insulating film 2, which causes a problem. In this way, in the comparative example, it is difficult to manufacture a semiconductor device including a silicon-containing aluminum film with a high shape accuracy.

### Test Example

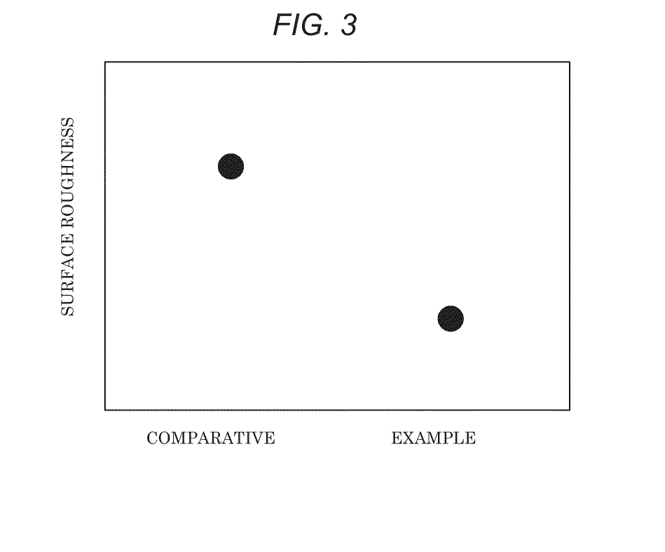

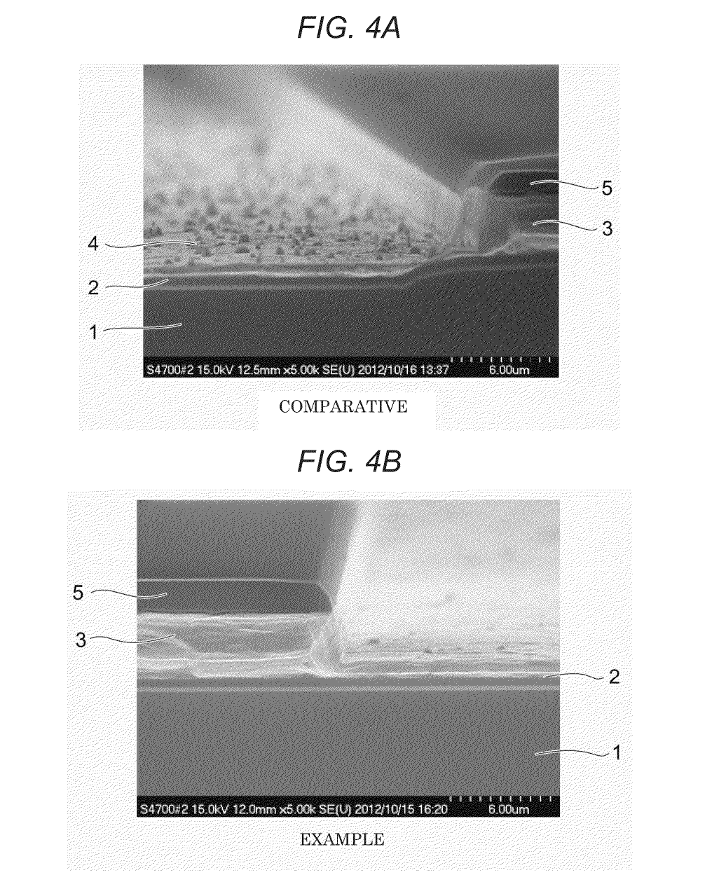

FIG. 3 is a graph illustrating advantageous effects of the embodiment in which the horizontal axis represents a sample and the vertical axis represents a surface roughness. FIG. 4A is a scanning electron microscopic (SEM) image of a sample according to the comparative example, and FIG. 4B is an SEM image of a sample according to an example of the embodiment.

In this test example, semiconductor devices are manufactured using the method according to the embodiment and the method according to the comparative example, and surface roughness of each top surface of interlayer insulating films thereof is compared with each other. Etching conditions are the same as those in the above-described embodiment. In a square region having a length of one side of 0.1 mm at the center of the silicon wafer 1, the surface roughness (average roughness Ra) of the top surface 2a of the interlayer insulating film 2 is measured using an atomic force microscope (AFM). The results are illustrated in FIG. 3. In addition, the surface after etching is observed by SEM. The results are illustrated in FIGS. 4A and 4B.

As illustrated in FIG. 3, in the example of the embodiment, when the silicon-containing aluminum film is etched, the surface roughness (Ra) of a substrate surface is less than that of the comparative example, and the flatness was higher than that of the comparative example.

In addition, as illustrated in FIG. 4A, in the sample of the comparative example, a large amount of the nodule 4 is remained on the interlayer insulating film 2 after etching. On the other hand, as illustrated in FIG. 4B, in the sample of the example of the embodiment, the nodule 4 is not observed.

### Second Embodiment

Next, a second embodiment will be described. In this embodiment, in the process of forming the AlSi film 3 illustrated in FIG. 1A, a heating temperature of the silicon wafer 1 is controlled to be higher than that of the first embodiment. For example, in the first embodiment, the temperature is lower than 455° C.; however, in this embodiment, the temperature is higher than or equal to 455° C. and is assumed as about 480° C. As a result, the AlSi film 3 can be effectively allowed to reflow, and the flatness of the top surface of the AlSi film 3 can be improved. However, since the film is allowed to reflow at a high temperature, the nodule 4 is greatly grown as compared to the first embodiment.

Therefore, in this embodiment, in the second dry-etching illustrated in FIG. 1C, a bias power is controlled to be higher than that of the first dry-etching. The bias power may be increased in one go when the first dry-etching is switched to the second dry-etching, that is, when the etching gas is changed; or may be stepwisely or continuously increased after the second dry-etching is started. As a result, since the sputtering property is improved as compared to the first embodiment, the nodule 4 having a larger size can be removed, and the top surface 2a of the interlayer insulating film 2 can be formed in a flat shape.

In this embodiment, the nodule 4 having a size close to the thickness of the AlSi film 3 before etching may be formed. In this case, a configuration may be adopted in which, when a part of the nodule 4 protrudes from the top surface of the AlSi film 3, the first dry-etching is stopped and the second dry-etching is started.

In this way, according to this embodiment, while securing the flatness of the top surface 2a of the interlayer insulating film 2 in the opening region 7, the flatness of the top surface of the AlSi film 3 can be improved in regions other than the opening region 7. In this embodiment, configurations and effects of the manufacturing method other than the above-described configurations and effects are the same as those of the first embodiment.

In the first and second embodiments, the examples in which the second dry-etching is stopped when the AlSi film 3 is removed in the opening region 7 are described. However, after the AlSi film 3 is removed in the opening region 7, the second dry-etching may be continued for a period of time, that is, over-etching may be performed.

According to the above-described embodiments, a method capable of manufacturing a semiconductor device including a silicon-containing aluminum film with a high shape accuracy can be realized.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
firstly dry-etching an aluminum film containing silicon with a first etching gas containing halogen to decrease the thickness of the aluminum film; and
secondly dry-etching the aluminum film with a second etching gas containing inert gas.

2. The method according to claim 1,
wherein the second etching gas contains halogen.

3. The method according to claim 2,
wherein a flow ratio of the inert gas in the second etching gas is set from 30% to 75% by volume.

4. The method according to claim 1,
wherein the first etching gas contains inert gas, and
a flow ratio of the inert gas in the first etching gas is lower than a flow rate of inert gas in the second etching gas.

5. The method according to claim 1,
wherein the halogen is chlorine.

6. The method according to claim 1,
wherein the inert gas is argon.

7. The method according to claim 1,
wherein the inert gas is nitrogen.

8. The method according to claim 1,
wherein the aluminum film contains a silicon nodule, and
after the completion of the first etching, the thickness of the aluminum film is greater than or equal to a maximum thickness of the nodule before the start of the second etching.

9. The method according to claim 8,
the first dry-etching is stopped when the a part of the silicon nodule protrudes from a top surface of the aluminum film and the second dry-etching is started.

10. The method according to claim 1,
wherein a bias power in the second etching is higher than a bias power in the first etching.

11. The method according to claim 10,
the bias power is increased in one go when the first dry-etching is switched to the second dry-etching or is stepwisely or continuously increased after the second dry-etching is started.

12. The method according to claim 1,
the second etching is continued to over-etching after the aluminum film is just removed.

13. The method according to claim 1, further comprising:
providing an interlayer insulating film on a wafer, and providing the aluminum film above the interlayer insulating film, before the first dry-etching of the aluminum film.

14. The method according to claim 13,
wherein the aluminum film is provided by sputtering.

15. The method according to claim 14,
wherein the wafer is heated at a temperature not more than 480° C.

16. The method according to claim 15,
wherein the wafer is heated at a temperature of near 430° C.

17. The method according to claim 13, further comprising:
providing a barrier layer on the interlayer insulating film, after providing the interlayer insulating film and before providing the aluminum film.

18. The method according to claim 17,
the barrier layer is selectively etched to the interlayer insulating film in the second-etching.
